(19) United States
(12) Patent Application Publication
(10) Pub. No.: US 2008/0144291 A1
(43) Pub. Date: Jun. 19, 2008

(54) METHODS AND DEVICES FOR COOLING PRINTED CIRCUIT BOARDS

(76) Inventors: Shao Chung Hu, Hsindian City (TW); Ming Chi Kan, Rende Township (TW); Chion-Min Sung, Taipei County (TW)

Correspondence Address: THORPE NORTH & WESTERN, LLP., P.O. Box 1219, SANDY, UT, 84091-1219, US

(21) Appl. No.: 11/610,313

(22) Filed: Dec. 13, 2006

(51) Int. Cl. H05K 7/20

(52) U.S. Cl. 361/720

(57) ABSTRACT

Methods and devices for cooling printed circuit boards having at least one heat source are disclosed and described. Such a device may include a dielectric layer disposed onto a surface of a substrate. The dielectric layer may include a plurality of carbonaceous particles disposed in a dielectric material. In one aspect, the carbonaceous particles may be diamond particles. Furthermore, a circuit including a heat source may be disposed onto a surface of the dielectric layer opposite to the substrate such that the circuit is thermally coupled to the dielectric layer. Additionally, the dielectric layer may be configured to accelerate heat generated by the heat source away from the heat source.

### FIELD OF THE INVENTION

The present invention relates generally to methods and associated devices for cooling printed circuit boards and other electronics devices. Accordingly, the present invention involves the electrical and material science fields.

### BACKGROUND OF THE INVENTION

In many developed countries, major portions of the populations consider electronic devices to be integral to their lives. Such increasing use and dependence has generated a demand for electronics devices that are smaller and faster. As electronic circuitry increases in speed and decreases in size, cooling of such devices becomes problematic.

Electronic devices generally contain printed circuit boards having integrally connected electronic components that allow the overall functionality of the device. These electronic components, such as processors, transistors, resistors, capacitors, light-emitting diodes (LEDs), etc., generate significant amounts of heat. As it builds, heat can cause various thermal problems associated with both the printed circuit board and internally in many electronic components. Significant amounts of heat can affect the reliability of an electronic device, or even cause it to fail by, for example, causing burn out or shorting both within the electronic components themselves and across the surface of the printed circuit board. Thus, the buildup of heat can ultimately affect the functional life of the electronic device. This is particularly problematic for electronic components with high power and high current demands, as well as for the printed circuit boards that support them.

The prior art often employs fans, heat sinks, Peltier and liquid cooling devices, etc., as means of reducing heat buildup in electronic devices. As increased speed and power consumption cause increasing heat buildup, such cooling devices generally must increase in size to be effective and also require power in and of themselves to operate. For example, fans must be increased in size and speed to increase airflow, and heat sinks must be increased in size to increase heat capacity and surface area. The demand for smaller electronic devices, however, not only precludes increasing the size of such cooling devices, but may also require a significant size decrease.

As a result, methods and associated devices are being sought to provide adequate cooling of electronic devices while minimizing size and power constraints placed on such devices due to cooling.

### SUMMARY OF THE INVENTION

Accordingly, the present invention provides thermally dynamic electronic circuit devices and methods for cooling such devices. In one aspect, for example, a thermally dynamic printed circuit board device for minimizing heat buildup is provided. Such a device may include a dielectric layer disposed onto a surface of a substrate. The dielectric layer may include a plurality of carbonaceous particles disposed in a dielectric material. In one aspect, the carbonaceous particles may be diamond particles. Furthermore, a circuit including a heat source may be disposed onto a surface of the dielectric layer opposite to the substrate such that the circuit is thermally coupled to the dielectric layer. Additionally, the dielectric layer may be configured to accelerate heat generated by the heat source away from the heat source.

The plurality of carbonaceous particles may be of a variety of sizes depending on the particular use and configuration of the printed circuit board. In one aspect, for example, the carbonaceous particles may be less than about 500 microns in size. In another aspect, the carbonaceous particles may be less than about 300 microns in size. In yet another example, the carbonaceous particles may be less than about 50 microns in size. Additionally, the proportion of carbonaceous particles included in the dielectric layer may vary depending on the thermal cooling requirements of a particular circuit board and various other factors, such as the thickness of the dielectric layer and various properties of the dielectric material. In one aspect, however, the plurality of carbonaceous particles may make up from about 1 vol % to about 90 vol % of the dielectric layer. In another aspect, the plurality of carbonaceous particles may make up from about 30 vol % to about 80 vol % of the dielectric layer.

The dielectric material used in the dielectric layer may include a variety of dielectric materials, provided such materials have dielectric properties capable of providing electrical isolation to the circuit. For example, in one aspect dielectric materials may include, without limitation, ceramic materials, glass materials, polymeric materials, and combinations thereof. Non-limiting examples of ceramic materials that may be used as dielectric materials may include Al₂O₃, MgO, BeO, ZnO, and combinations thereof. In one specific aspect, a ceramic dielectric material may include Al₂O₃. Non-limiting examples of glass materials that may be used as dielectric materials may include Li₂O-Al₂O₃-SiO₂ based materials, MgO-Al₂O₃-SiO₂ based materials, Li₂O—MgO—SiO₂ based materials, Li₂O—ZnO—SiO₂ based materials, and combinations thereof. Non-limiting examples of polymeric materials that may be used as dielectric materials may include amino resins, acrylate resins, alkyd resins, polyester resins, polyamide resins, polyimide resins, polyurethane resins, phenolic resins, phenolic/latex resins, epoxy resins, isocyanate resins, isocyanurate resins, polysiloxane resins, reactive vinyl resins, polyethylene resins, polypropylene resins, polystyrene resins, phenoxy resins, perylene resins, polysulfone resins, acrylonitrile-butadiene-styrene resins, acrylic resins, polycarbonate resins, polyimide resins, and combinations thereof.

In another aspect of the present invention, a method for cooling a printed circuit board is provided. Such a method may include providing a circuit including a heat source, the circuit being disposed on a surface of a dielectric layer. The dielectric layer may include a plurality of carbonaceous particles disposed in a dielectric material such that, upon passing an electrical current through the circuit, heat generated by the circuit is accelerated away from the heat source through the dielectric layer. The heat source associated with the circuit may include both active and passive heat sources. One example of an active heat source may include a heat-generating electronic component. Additionally, in one aspect the carbonaceous particles may be diamond particles.

In yet another aspect of the present invention, a method of cooling the printed circuit boards as recited herein. Such a method may include activating the heat source such that heat generated by the heat source is accelerated away from the heat source through the dielectric layer.

In a further aspect of the present invention, a method of making a thermally dynamic printed circuit board is provided. Such a method may include depositing a dielectric layer on a substrate, the dielectric layer including a plurality of carbonaceous particles disposed in a dielectric material. The method may also include forming a circuit on the dielectric layer opposite to the substrate. In some aspects, the method may further include thermally coupling a heat source to the circuit. Additionally, in one aspect the carbonaceous particles may be diamond particles.

The dielectric layer may be deposited on the substrate using a variety of techniques, all of which are considered to be within the scope of the present invention. In one aspect, for example, depositing the dielectric layer may further include disposing a plurality of carbonaceous particles in an aluminum matrix, the plurality of carbonaceous particles being disposed at least along an edge of the aluminum matrix. The aluminum matrix may then be anodized along the edge to form a dielectric Al₂O₃ layer having a plurality of carbonaceous particles disposed therein. In some aspects utilizing the dielectric Al₂O₃ layer, the aluminum matrix may be the substrate.

In another aspect, depositing the dielectric layer may further include mixing a plurality of carbonaceous particles in a dielectric material and disposing the carbonaceous particle-containing dielectric material onto the substrate.

Numerous types of devices may be constructed according to aspects of the present invention. For example, in one aspect, a light-emitting diode chips and devices having improved heat dissipation properties is provided. Such a device may include a light-emitting diode thermally coupled to the circuit of the printed circuit board as described herein, such that the dielectric layer is configured to accelerate heat movement away from the light-emitting diode. In another example, a thermally dynamic printed circuit board device having improved heat dissipation properties is provided. Such a device may include a central processing unit thermally coupled to the printed circuit board as described herein, such that the dielectric layer is configured to accelerate heat movement away from the central processing unit.

Additionally, in one specific aspect a thermally dynamic printed circuit board device for minimizing heat buildup is provided. Such a device may include an aluminum matrix having a plurality of diamond particles disposed therein and an Al₂O₃ dielectric layer disposed onto a surface of the aluminum matrix, where dielectric layer is physically coupled to a portion of the plurality of diamond particles. A circuit including a heat source may be disposed onto the dielectric layer opposite to the aluminum matrix. The dielectric layer is thus configured to accelerate heat generated by the heat source away from the heat source. In one aspect, a portion of the plurality of diamond particles may partially protrude from a surface of the aluminum matrix opposite the dielectric layer.

There has thus been outlined, rather broadly, various features of the invention so that the detailed description thereof that follows may be better understood, and so that the present contribution to the art may be better appreciated. Other features of the present invention will become clearer from the following detailed description of the invention, taken with the accompanying claims, or may be learned by the practice of the invention.

### BRIEF DESCRIPTION OF THE DRAWINGS

FIG. 1 is a cross-section view of a printed circuit board in accordance with one embodiment of the present invention.

FIG. 2 is a cross-section view of a printed circuit board in accordance with another embodiment of the present invention.

FIG. 3 is a cross-section view of a printed circuit board in accordance with yet another embodiment of the present invention.

FIG. 4 is a cross-section view of a printed circuit board in accordance with a further embodiment of the present invention.

FIG. 5 is a cross-section view of a printed circuit board in accordance with another embodiment of the present invention.

FIG. 6 is a cross-section view of a printed circuit board in accordance with yet another embodiment of the present invention.

### DETAILED DESCRIPTION OF THE INVENTION

Definitions

In describing and claiming the present invention, the following terminology will be used in accordance with the definitions set forth below.

The singular forms “a,” “an,” and, “the” include plural referents unless the context clearly dictates otherwise. Thus, for example, reference to “a heat source” includes reference to one or more of such sources, and reference to “the dielectric layer” includes reference to one or more of such layers.

The terms “heat transfer,” “heat movement,” and “heat transmission” can be used interchangeably, and refer to the movement of heat from an area of higher temperature to an area of cooler temperature. It is intended that the movement of heat include any mechanism of heat transmission known to one skilled in the art, such as, without limitation, conductive, convective, radiative, etc.

As used herein, “printed circuit board” and “circuit board” may be used to describe any circuit structure of chips and package level structures of an electrical device. In one aspect, the circuit board may include a substrate, a dielectric layer, and conductive traces.

As used herein, “dielectric material” is used to describe any material having significant electrical insulating properties.

As used herein, “dynamic” or “dynamically” or “thermally dynamic” refers to a characteristic of a material wherein the material is active at transferring energy. Generally, the dynamic material is active at transferring thermal energy.

As used herein, “heat source” refers to a device or object having an amount of thermal energy or heat which is greater than an immediately adjacent region. In printed circuit boards, for example, a heat source can be any region of the board that is hotter than an adjacent region. Heat sources can include devices that produce heat as a byproduct of their operation (hereinafter known as “primary heat sources” or “active heat sources”), as well as objects that become heated by a transfer of heat energy thereto (hereinafter known as “secondary heat sources” or “passive heat sources”). Examples of primary or active heat sources include without limitation, CPU's, electrical traces, LED's, etc. Examples of secondary or passive heat sources include without limitation, heat spreaders, heat sinks, etc.

As used herein, the terms “conductive trace” and “conduction trace” refer to conductive pathways on a printed circuit board that are capable of conducing heat, electricity, or both.

The term “ceramic” refers to a compound of nonmetallic and metallic or semimetallic elements, for which the interatomic bonding is predominantly ionic. Ceramic also includes cermet materials.

As used herein, “particle” and “grit” may be used interchangeably, and when used in connection with a carbonaceous material, refer to a particulate form of such material. Such particles or grits may take a variety of shapes, including round, oblong, square, euhedral, etc., as well as a number of specific mesh sizes. As is known in the art, “mesh” refers to the number of holes per unit area as in the case of U.S. meshes. All mesh sizes referred to herein are U.S. mesh unless otherwise indicated. Further, mesh sizes are generally understood to indicate an average mesh size of a given collection of particles since each particle within a particular “mesh size” may actually vary over a small distribution of sizes.

As used herein, “vapor deposition” refers to a process of depositing materials on a substrate through the vapor phase. Vapor deposition processes can include any process such as, but not limited to, chemical vapor deposition (CVD) and physical vapor deposition (PVD). A wide variety of variations of each vapor deposition method can be performed by those skilled in the art. Examples of vapor deposition methods include hot filament CVD, rf-CVD, laser CVD (LCVD), metal-organic CVD (MOCVD), sputtering, thermal evaporation PVD, ionized metal PVD (IMPVD), electron beam PVD (EBPVD), reactive PVD, and the like.

As used herein, “chemical vapor deposition,” or “CVD” refers to any method of chemically depositing diamond particles in a vapor form upon a surface. Various CVD techniques are well known in the art.

As used herein, “physical vapor deposition,” or “PVD” refers to any method of physically depositing diamond particles in a vapor form upon a surface. Various PVD techniques are well known in the art.

As used herein, “carbonaceous” refers to any material which is made primarily of carbon atoms. A variety of bonding arrangements or “allotropes” are known for carbon atoms, including planar, distorted tetrahedral, and tetrahedral bonding arrangements. As is known to those of ordinary skill in the art, such bonding arrangements determine the specific resultant material, such as graphite, diamond-like carbon, or amorphous diamond, and pure diamond. In one aspect, the carbonaceous material may be diamond.

As used herein, “diamond” refers to a crystalline structure of carbon atoms bonded to other carbon atoms in a lattice of tetrahedral coordination known as Sp³ bonding. Specifically, each carbon atom is surrounded by and bonded to four other carbon atoms, each located on the tip of a regular tetrahedron. The structure and nature of diamond, including its physical and electrical properties are well known in the art.

As used herein, “diamond-like carbon” refers to a carbonaceous material having carbon atoms as the majority element, with a substantial amount of such carbon atoms bonded in distorted tetrahedral coordination. Diamond-like carbon (DLC) can typically be formed by PVD processes, although CVD or other processes could be used such as vapor deposition processes. Notably, a variety of other elements can be included in the DLC material as either impurities, or as dopants, including without limitation, hydrogen, sulfur, phosphorous, boron, nitrogen, silicon, tungsten, etc.

As used herein, “deposited” and “depositing,” with respect to a printed circuit board, refers to an area along at least a portion of an outer surface of the printed circuit board that has been intimately contacted with a layer of heat conductive material, and, as such, thermal coupling has been achieved. In some aspects, the deposited material may be a layer which substantially covers an entire surface of the printed circuit board. In other aspects, the deposited material may be a layer which covers only a portion of a surface of the printed circuit board.

As used herein, the term “substantially” refers to the complete or nearly complete extent or degree of an action, characteristic, property, state, structure, item, or result. For example, an object that is “substantially” enclosed would mean that the object is either completely enclosed or nearly completely enclosed. The exact allowable degree of deviation from absolute completeness may in some cases depend on the specific context. However, generally speaking the nearness of completion will be so as to have the same overall result as if absolute and total completion were obtained. The use of “substantially” is equally applicable when used in a negative connotation to refer to the complete or near complete lack of an action, characteristic, property, state, structure, item, or result. For example, a composition that is “substantially free of” particles would either completely lack particles, or so nearly completely lack particles that the effect would be the same as if it completely lacked particles. In other words, a composition that is “substantially free of” an ingredient or element may still actually contain such item as long as there is no measurable effect thereof.

As used herein, the term “about” is used to provide flexibility to a numerical range endpoint by providing that a given value may be “a little above” or “a little below” the endpoint.

As used herein, a plurality of items, structural elements, compositional elements, and/or materials may be presented in a common list for convenience. However, these lists should be construed as though each member of the list is individually identified as a separate and unique member. Thus, no individual member of such list should be construed as a de facto equivalent of any other member of the same list solely based on their presentation in a common group without indications to the contrary.

Concentrations, amounts, and other numerical data may be expressed or presented herein in a range format. It is to be understood that such a range format is used merely for convenience and brevity and thus should be interpreted flexibly to include not only the numerical values explicitly recited as the limits of the range, but also to include all the individual numerical values or sub-ranges encompassed within that range as if each numerical value and sub-range is explicitly recited. As an illustration, a numerical range of “about 1 to about 5” should be interpreted to include not only the explicitly recited values of about 1 to about 5, but also include individual values and sub-ranges within the indicated range. Thus, included in this numerical range are individual values such as 2, 3, and 4 and sub-ranges such as from 1-3, from 2-4, and from 3-5, etc., as well as 1, 2, 3, 4, and 5, individually.

This same principle applies to ranges reciting only one numerical value as a minimum or a maximum. Furthermore, such an interpretation should apply regardless of the breadth of the range or the characteristics being described.

The Invention

One promising material that has been explored for use in heat dissipation devices is diamond. Diamond materials can carry away heat much faster than any other material. The thermal conductivity of diamond at room temperature (about 2000 W/mK) is five times higher than copper (about 400 W/mK) and eight times that of aluminum (250 W/mK), the two fastest metal heat conductors commonly used. Moreover, the thermal diffusivity of diamond (12.7 cm²/sec) is eleven times that of copper (1.17 cm²/sec) or aluminum (0.971 cm²/sec). The ability for diamond to carry away heat without storing it makes diamond an ideal material for use in the dissipation of heat.

In recent years diamond heat spreaders have been used to dissipate heat from high power laser diodes, such as that used by laser diodes to boost the light energy in optical fibers. However, large area diamonds are very expensive; hence, diamond has not been commercially used to spread the heat generated by CPUs, LEDs, and other common electronics components.

Many such diamond heat dissipation devices are made of diamond films formed by chemical vapor deposition (CVD). The high expense of CVD diamond films prohibit diamond heat spreaders from being widely used except in those applications (e.g., high power laser diodes) where only a small area is required or no effective alternative heat spreaders are available. Additionally, CVD diamond films are often very thin, and may not resist thermal stress from coefficient of thermal expansion mismatch with the underlying surface.

In order to overcome these limitations, it has been discovered that carbonaceous particles, including diamond materials, having high thermal conductivity can be disposed into a dielectric material and coated onto the surface of a printed circuit board or other electronic device in order to accelerate heat transfer away from hot spots. Thus a printed circuit board can be effectively cooled by accelerated heat transfer laterally across the surface of the board and accelerated heat transfer to the air as the heat spreads laterally.

Accordingly, the present invention provides thermally dynamic electronic circuit devices having carbonaceous materials that are effective at dissipating heat that do not suffer from many of the above mentioned problems. In one aspect for example, a thermally dynamic printed circuit board device for minimizing heat buildup is provided. Such a device may include a dielectric layer disposed onto a surface of a substrate, where the dielectric layer includes a plurality of carbonaceous particles disposed in a dielectric material. The device may further include a heat source-containing circuit disposed onto a surface of the dielectric layer that is opposite to the substrate. The circuit and heat source are thermally coupled to the dielectric layer, and thus the dielectric layer is configured to accelerate heat generated by the heat source away from the heat source.

It should be noted that any form of heat source known to introduce heat into a printed circuit board or other electronic device that is known to one skilled in the art is considered to be within the scope of the present invention. In one aspect the heat source can be an active heat source, an example of which may be a heat-generating electronic component. Such components may include, without limitation, resistors, capacitors, transistors, processing units including central and graphics processing units, LEDs, laser diodes, filters, etc. Heat sources can also include regions of a printed circuit board containing a high density of conductive traces, and regions receiving transmitted heated from a heat source that is not in physical contact with the printed circuit board. They can also include heat sources in physical contact with, but not considered integral to the printed circuit board. An example of this may be a motherboard having a daughterboard coupled thereto, where heat is transferred from the daughterboard to the motherboard.

Irrespective of the source, the transfer of heat present in the printed circuit board can be accelerated away from the heat source through the carbonaceous particles disposed in the dielectric layer. It should be noted that the present invention is not limited as to specific theories of heat transmission. As such, in one aspect the accelerated movement of heat away from the heat source can be at least partially due to heat movement laterally through the plurality of carbonaceous particles. Due to the heat conductive properties of diamond and other carbonaceous materials, heat can rapidly spread laterally through the carbonaceous particles across the surface of the printed circuit board. Such accelerated heat transfer may result in printed circuit boards with much cooler operational temperatures.

The acceleration of heat transfer away from a heat source not only cools the printed circuit board, but also may reduce the heat load on many electronic components that are cooled primarily to the air surrounding the printed circuit board. For example, a central processing unit (CPU) having an external heat sink and fan may require less external cooling due to the improved heat transmission through the printed circuit board via the CPU socket.

As has been described, carbonaceous materials may be used to rapidly transmit heat away from a heat source. Any size of carbonaceous particle that can be disposed in a dielectric layer and used to transmit heat away from a heat source may be utilized according to aspects of the present invention. In one aspect, however, the carbonaceous particles may be less than about 500 microns in size. In another aspect, the carbonaceous particles may be less than about 300 microns in size. In yet another aspect, the carbonaceous particles may be less than about 50 microns in size. Additionally, the plurality of carbonaceous particles disposed in the dielectric layer may be of the same or similar size, or they may be of various sizes. By using carbonaceous particles of varying sizes, for example, smaller particles may be used to fill the spaces between larger particles, thus increasing the density of the carbonaceous material in the dielectric layer. By increasing the density of the carbonaceous material in the dielectric layer, the proportion or overall level of contacts between carbonaceous particles is increased, and thus heat transfer should similarly be increased. It should be noted, however, that the level of contacts between the plurality of carbonaceous particles may vary for a particular circuit board depending on the intended use of the electronic device and the desired level of heat dissipation for a particular application. In one aspect, for example, a very high level of contact between the particles may be desirable. Such a high level of contact may be achieved by utilizing carbonaceous particles with a uniform size and shape, such as, for example, cubes, to allow efficient packing. To further increase the level of contact, smaller carbonaceous particles may be disposed into gaps or spaces between the larger particles. In another aspect where a lower level of heat dissipation is required, a lower proportion of carbonaceous particles may be disposed in the dielectric layer. In some cases, there may be little if any contact between the particles. In yet another aspect, a distribution of sizes and/or shapes of carbonaceous particles may be disposed in the dielectric material to form the dielectric layer. Accordingly, there may be significant variation in the amount of carbonaceous particles included in the dielectric layer. For example, in one aspect, the plurality of carbonaceous particles may make up from about 1 vol % to about 90 vol % of the dielectric layer. In another aspect, the plurality of carbonaceous particles may make up from about 30 vol % to about 80 vol % of the dielectric layer.

As has been described, the dielectric layer is a layer of dielectric material having a plurality of carbonaceous particles disposed therein. The dielectric material provides electrical isolation properties to the dielectric layer for the circuit or circuits disposed thereon, while at the same time bonding the carbonaceous particles to the circuit board to allow effective thermal movement. The dielectric layer can thus be coated on various portions of the printed circuit board, depending on factors such as the intended use of the circuit board, potential temperatures the circuit board may attain, manufacturing costs, etc. As will be discussed further below, the dielectric layer can be coated on a portion, one side, or both sides of the printed circuit board. The dielectric layer may be disposed on an entire surface, or upon only a portion of a surface. For example, the dielectric layer may be disposed on substantially the entire surface of the substrate over which the circuit is disposed. This may be particularly critical where conductive materials such as metals are used for the substrate. Furthermore, an additional dielectric layer may be disposed on an opposite surface of the substrate from the primary dielectric layer.

Additionally, diamond-like carbon materials may optionally be used to assist in the transmission of heat away from a heat source. In one aspect, for example, a diamond-like carbon layer may be disposed onto a surface of the substrate that is opposite to the surface onto which the dielectric layer is disposed. Such a diamond-like carbon layer may facilitate the movement of heat directly to the air. The thickness of such a layer may vary depending on the cooling requirements of a particular application. That being said, in one aspect the layer of diamond-like carbon can be from about 0.1 micrometer to about 50 micrometers thick. In another aspect, the layer of diamond-like carbon can be from about 0.1 micrometer to about 10 micrometers thick. Further details on utilizing diamond-like carbon layers to cool printed circuit board can be found in U.S. patent application Ser. No. 11/201,771, filed on Aug. 10, 2005, which is incorporated herein be reference.

With respect to diamond-like carbon layers, a number of specific methods and techniques are known for deposition onto a substrate including physical vapor deposition (PVD) and chemical vapor deposition (CVD). In accordance with the present invention, any suitable deposition process may be used to create the diamond-like carbon layer. Further, specific deposition conditions may be used in order to adjust the exact type of material to be deposited, whether diamond-like carbon, amorphous diamond, or pure diamond. In one embodiment, a diamond-like carbon layer may be deposited onto a printed circuit board through a PVD sputtering process. In another embodiment, the diamond-like carbon layer may be deposited by a thermal evaporation PVD process.

A variety of dielectric materials may be utilized in the dielectric layer, depending on the nature and intended use of the circuit board. It is important that the dielectric material be capable of electrically isolating the circuit disposed thereon. Though any known dielectric material ma be used, examples may include, without limitation, ceramic materials, glass materials, polymeric materials, and combinations thereof. In one aspect, non-limiting examples of useful ceramic materials may include, for example, Al₂O₃, MgO, BeO, ZnO, and combinations thereof In one specific aspect, the ceramic material may include Al₂O₃. In another aspect, non-limiting examples of glass materials may include, without limitation, Li₂O—Al₂O₃—SiO₂ based materials, MgO—Al₂O₃—SiO₂ based materials, Li₂O—MgO—SiO₂ based materials, Li₂O—ZnO—SiO₂ based materials, and combinations thereof. In yet another aspect, non-limiting examples of useful polymeric materials may include amino resins, acrylate resins, alkyd resins, polyester resins, polyamide resins, polyimide resins, polyurethane resins, phenolic resins, phenolic/latex resins, epoxy resins, isocyanate resins, isocyanurate resins, polysiloxane resins, reactive vinyl resins, polyethylene resins, polypropylene resins, polystyrene resins, phenoxy resins, perylene resins, polysulfone resins, acrylonitrile-butadiene-styrene resins, acrylic resins, polycarbonate resins, polyimide resins, and combinations thereof.

Furthermore, the thickness of the dielectric layer may be variable, depending on the size and nature of the carbonaceous particles used and the nature and intended use of the circuit board. In one aspect, however, the dielectric layer may be from about 1 micron thick to about 500 microns thick. In another aspect, the dielectric layer may be from about 500 microns thick to about 1000 microns thick. In yet another aspect, the dielectric layer may be less than 100 microns thick. In a further aspect, the dielectric layer may be less than about 300 microns thick.

As has been described, the dielectric material is utilized to couple the carbonaceous particles to the substrate in order to provide electrical isolation to the circuit disposed thereon. As such, a variety of substrate materials may be utilized to form the structure of a circuit board, regardless of that material's dielectric nature. For example, the substrate may be a metal material such as aluminum. By disposing a circuit onto the dielectric layer, substrate materials such as metals may be utilized in the construction of various electronic devices. In addition to metals, a variety of ceramic and polymeric materials may be used as substrates. Such materials are well known in the art, and may vary depending on the nature and intended use of the circuit board.

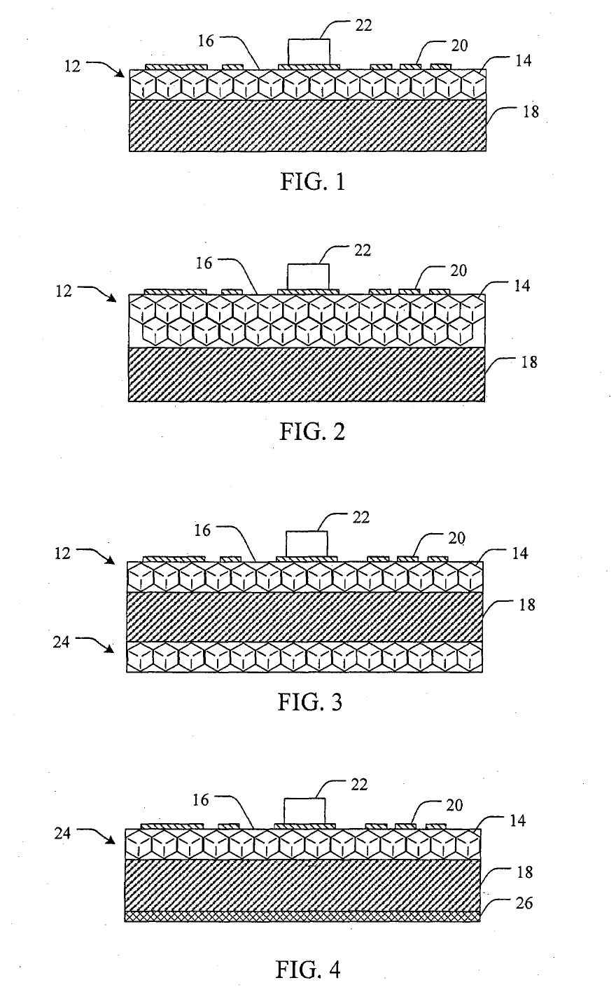

Turning to FIG. 1, a printed circuit board is shown having a dielectric layer 12 that includes a plurality of carbonaceous particles 14 disposed in a dielectric material 16. The dielectric layer 12 is disposed onto a substrate 18 for support. As has been noted, due to the insulative properties of the dielectric layer 12, the support 18 may be any know supportive material, including both conductive and nonconductive materials. A circuit 20 is disposed onto the dielectric layer 12. The circuit 20 may be thermally coupled to a heat source 22. Thus, heat generated by the heat source 22 and the circuit 20 is conducted into the underlying dielectric layer 12 and into the carbonaceous particles 14. The carbonaceous particles 14 spread the heat laterally through the dielectric layer 12, into the substrate 18, and into surrounding cooler regions including the air.

Methods for depositing circuits and circuit components are well known in the art, and one of ordinary skill would readily understand such methods once in possession of the present disclosure. It is understood that a particular dielectric material may be chosen to facilitate the deposition of circuitry. As an example, circuitry may readily be deposited onto Al₂O₃ to form a circuit board having good insulation properties between the conductive lines of the circuit and other circuit elements.

It is contemplated that a variety of heat sources may be cooled according to various aspects of the present invention. For example, the heat source may be a central or graphics processing unit, an LED, a laser diode, a filter such as a surface acoustic wave filter, etc. In one aspect, for example, an LED device having improved heat dissipation properties may be provided. Such a device may include a light-emitting diode thermally coupled to the circuit of a device as described herein. As such, the dielectric layer is configured to accelerate heat movement away from the light-emitting diode. As they have become increasingly important in electronics and lighting devices, LEDs continue to be developed that have ever increasing power requirements. This trend of increasing power has created cooling problems for these devices. These cooling problems can be exacerbated by the typically small size of these devices, which may render heat sinks with traditional aluminum heat fins ineffective due to their bulky nature. By cooling an LED according to aspects of the present invention, adequate cooling even at very high power can be achieved, while maintaining a small LED package size.

In another aspect, a thermally dynamic printed circuit board device having improved heat dissipation properties is provided. Such a device may include a central processing unit thermally coupled to the circuit of a device as described herein. Thus, the dielectric layer is configured to accelerate heat movement away from the central processing unit.

It should be noted that, although FIG. 1 depicts a single layer of carbonaceous particles that come into direct contact with each other, numerous configurations of the dielectric layer are possible, all of which are considered to be within the present scope. For example, FIG. 2 shows an aspect of the present invention wherein the dielectric layer 12 is comprised of multiple rows of carbonaceous particles 14 in the dielectric material 16. Although FIG. 2 shows two rows of carbonaceous particles 14, it should be noted that any number of rows of particles are contemplated. Additionally, the carbonaceous particles may be arranged in the dielectric material in configurations that are less uniform than that shown in FIG. 2. Additionally, although similar size particles are shown, particles of varying sizes may be used.

Turning to FIG. 3, in some aspects an additional dielectric layer 24 may be disposed onto a surface that is opposite to the dielectric layer 12. Such a configuration may facilitate the cooling of the circuit board from at least two sides, thus more effectively accelerating heat from the heat source 22. An additional dielectric layer 24 may have carbonaceous particles 14 disposed in the dielectric material 16 as has been described, or the additional dielectric layer 24 may lack the carbonaceous particles and consist merely of the dielectric material (not shown). Furthermore, circuits and circuit elements may also be deposited onto the additional dielectric layer (not shown).

As is shown in FIG. 4, in some aspects a diamond-like carbon layer 26 may be disposed onto a surface of the substrate 18 that is opposite to the dielectric layer 12. As has been described, the diamond-like carbon layer may facilitate the movement of heat from the substrate 18 to the air.

In other aspects of the present invention, various methods of making and cooling printed circuit boards are provided. For example, in one aspect a method for cooling a printed circuit board may include providing a circuit including a heat source, the circuit being disposed on a surface of a dielectric layer. Such a dielectric layer may include a plurality of carbonaceous particles disposed in a dielectric material such that, upon passing an electrical current through the circuit, heat generated by the circuit is accelerated away from the heat source through the dielectric layer.

In another aspect, a method of making a thermally dynamic printed circuit board is provided. Such a method may include depositing a dielectric layer on a substrate, where the dielectric layer may include a plurality of carbonaceous particles disposed in a dielectric material. A circuit may subsequently be formed on the dielectric layer opposite to the substrate. In another aspect, a heat source may be thermally coupled to the circuit.

Various methods of depositing a dielectric layer onto the substrate are also contemplated. Such methods may vary depending on the nature of the dielectric material used in the dielectric layer. For example, in one aspect the plurality of carbonaceous particles may be mixed with a dielectric material. Subsequently, the carbonaceous particle-containing dielectric material may be disposed onto the substrate to form the dielectric layer. Such deposition may be accomplished by a variety of methods known to those of ordinary skill in the art, including knife casting, spraying, etc. The dielectric material may be allowed to harden, or it may be heated or reacted with a catalyst, depending on the nature of the material. In a similar aspect, carbonaceous particles may be deposited onto the substrate and a dielectric material may be disposed thereon. In such a case, a mold may be beneficial to hold the diamonds and the dielectric material during application and curing.

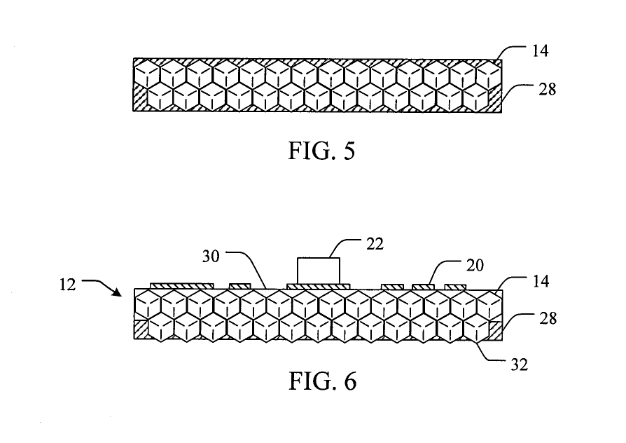

In another aspect of the present invention, a portion of a metal substrate may be converted into the dielectric layer. In such a method, a plurality of carbonaceous particles may be disposed into a metal matrix, such as aluminum. The plurality of carbonaceous particles should be located at least along an edge of the aluminum matrix. In one aspect, as is shown in FIG. 5, the carbonaceous particles 14 may be disposed throughout the aluminum matrix 28. As is shown in FIG. 6, the aluminum matrix 28 along an edge containing the carbonaceous particles 14 may be anodized to form a dielectric Al₂O₃ layer 30 having a plurality of carbonaceous particles 14 disposed therein. Thus the dielectric layer 12 containing the carbonaceous particles 14 may be formed from the substrate having embedded carbonaceous particles. In this way, a dielectric layer having high insulating characteristics and high thermal conductivity may be utilized to cool the circuit board. Subsequently, circuits 20 and heat sources 22 may be disposed on the dielectric layer 12. Furthermore, in some aspects emission of heat to the air may be facilitated by exposing the carbonaceous particles 32 from the metal matrix 28 on the surface opposite to the circuit. In this way, heat that is transmitted through the plurality of carbonaceous particles may be further transferred to the air through the exposed portions of the particles. Although any method of exposure is considered to be within the present scope, non-limiting examples include grit blasting, chemical erosion, abrading, etc.

### EXAMPLES

The following examples illustrate various techniques of making a thermally dynamic printed circuit board according to aspects of the present invention. However, it is to be understood that the following are only exemplary or illustrative of the application of the principles of the present invention. Numerous modifications and alternative compositions, methods, and systems can be devised by those skilled in the art without departing from the spirit and scope of the present invention. The appended claims are intended to cover such modifications and arrangements. Thus, while the present invention has been described above with particularity, the following Examples provide further detail in connection with several specific embodiments of the invention.

### Example 1

45/50 US mesh diamond particles are acid cleaned and loaded into a mold. Liquid aluminum is infiltrated into the mold with 30-80 vol % diamond particles and with a pressure of 10˜500 MPa. The thickness of the diamond/Al composite is greater than about 0.5 mm, depending on the size of the diamond particles. The diamond/Al composite is then anodized by hot water (˜100° C.) and cold water (<10° C.). The result is a diamond/Alumina dielectric layer on the top of diamond/Al composite.

### Example 2

A diamond/Alumina dielectric layer is made as described in Example 1, with the exception that 140/170 US mesh diamond particles are used.

### Example 3

A diamond/Alumina dielectric layer is made as described in Example 1, with the exception that two or more different sizes of diamond particles are used to improve the package density or solid content. Higher package density or solid content would increase the thermal conductivity of dielectric layer.

### Example 4

A diamond/Alumina dielectric layer is made as described in Example 1, with the exception that the diamond particles are pre-coated with Si, Ti, W, or Cr, to improve the bonding strength between the diamond and the Al matrix.

### Example 5

A plurality of diamond particles are arranged on a surface of a Si substrate, and the substrate is placed into a mold. Liquid aluminum is infiltrated into the mold with a pressure of 10˜500 MPa. The diamond/Al composite is anodized by hot water (˜100° C.) and cold water (<10° C.). The result is diamond/Alumina dielectric layer on the top of a composite of diamond/Aluminum/Si.

### Example 6

The circuit board with the diamond/Alumina dielectric layer as described in Example 5 is used for chip scale packages, which may include chip-on-board packages or system-on-board packages). Such a device may directly contact semiconductor chips to improve all thermal issues of many high power chips.

Of course, it is to be understood that the above-described arrangements are only illustrative of the application of the principles of the present invention. Numerous modifications and alternative arrangements may be devised by those skilled in the art without departing from the spirit and scope of the present invention and the appended claims are intended to cover such modifications and arrangements. Thus, while the present invention has been described above with particularity and detail in connection with what is presently deemed to be the most practical and preferred embodiments of the invention, it will be apparent to those of ordinary skill in the art that numerous modifications, including, but not limited to, variations in size, materials, shape, form, function and manner of operation, assembly and use may be made without departing from the principles and concepts set forth herein.

What is claimed is:

1. A thermally dynamic printed circuit board device for minimizing heat buildup, comprising:
a dielectric layer disposed onto a surface of a substrate, said dielectric layer including a plurality of carbonaceous particles disposed in a dielectric material; and
a circuit including a heat source, said circuit being disposed onto a surface of the dielectric layer opposite to the substrate and being thermally coupled to the dielectric layer, said dielectric layer being configured to accelerate heat generated by the heat source away from the heat source.

2. The device of claim 1, wherein the carbonaceous particles are less than about 500 microns in size.

3. The device of claim 1, wherein the carbonaceous particles are less than about 300 microns in size.

4. The device of claim 1, wherein the carbonaceous particles are less than about 50 microns in size.

5. The device of claim 1, wherein the carbonaceous particles are diamond particles.

6. The device of claim 1, wherein the dielectric material includes a member selected from the group consisting of ceramic materials, glass materials, polymeric materials, and combinations thereof.

7. The device of claim 6, wherein the ceramic material may include a member selected from the group consisting of Al₂O₃, MgO, BeO, ZnO, and combinations thereof.

8. The device of claim 7, wherein the ceramic material may include Al₂O₃.

9. The device of claim 6, wherein the glass material may include a member selected from the group consisting of Li₂O—Al₂O₃—SiO₂ based materials, MgO—Al₂O₃—SiO₂ based materials, Li₂O—MgO—SiO₂ based materials, Li₂O—ZnO—SiO₂ based materials, and combinations thereof.

10. The device of claim 6, wherein the polymeric materials may include a member selected from the group consisting of amino resins, acrylate resins, alkyd resins, polyester resins, polyamide resins, polyimide resins, polyurethane resins, phenolic resins, phenolic/latex resins, epoxy resins, isocyanate resins, isocyanurate resins, polysiloxane resins, reactive vinyl resins, polyethylene resins, polypropylene resins, polystyrene resins, phenoxy resins, perylene resins, polysulfone resins, acrylonitrile-butadiene-styrene resins, acrylic resins, polycarbonate resins, polyimide resins, and combinations thereof.

11. The device of claim 1, wherein the dielectric layer may be from about 1 micron to about 500 microns thick.

12. The device of claim 1, wherein the substrate is a metal material.

13. The device of claim 12, wherein the metal material is aluminum.

14. The device of claim 1, wherein the substrate is a ceramic material.

15. The device of claim 1, wherein the substrate is a polymeric material.

16. The device of claim 1, wherein an additional dielectric layer is disposed on an opposite surface of the substrate from the dielectric layer.

17. The device of claim 1, wherein the dielectric layer is disposed on at least substantially all of the substrate over which the circuit is disposed.

18. The device of claim 1, wherein in the plurality of carbonaceous particles make up from about 1 vol % to about 90 vol % of the dielectric layer.

19. The device of claim 1, wherein in the plurality of carbonaceous particles make up from about 30 vol % to about 80 vol % of the dielectric layer.

20. The device of claim 1, further comprising a layer of diamond-like carbon disposed on an opposite surface from the dielectric layer.

21. A method for cooling a printed circuit board, comprising:
providing a circuit including a heat source, said circuit disposed on a surface of a dielectric layer, said dielectric layer including a plurality of carbonaceous particles disposed in a dielectric material such that upon passing an electrical current through the circuit, heat generated by the circuit is accelerated away from the heat source through the dielectric layer.

22. The method of claim 21, wherein the heat source is an active heat source.

23. The method of claim 22, wherein the active heat source is a heat-generating electronic component.

24. A method of cooling the printed circuit board as recited in claim 21, comprising:
activating the heat source such that heat generated by the heat source is accelerated away from the heat source through the dielectric layer.

25. A method of making a thermally dynamic printed circuit board, comprising:
depositing a dielectric layer on a substrate, said dielectric layer including a plurality of carbonaceous particles disposed in a dielectric material; and
forming a circuit on the dielectric layer opposite to the substrate.

26. The method of claim 25, further including thermally coupling a heat source to the circuit.

27. The method of claim 25, wherein depositing a dielectric layer further includes:
disposing a plurality of carbonaceous particles in an aluminum matrix, said plurality of carbonaceous particles being disposed at least along an edge of the aluminum matrix;
anodizing the aluminum matrix along the edge to form a dielectric Al₂O₃ layer having a plurality of carbonaceous particles disposed therein.

28. The method of claim 27, wherein the aluminum matrix is the substrate.

29. The method of claim 25, wherein depositing a dielectric layer further includes:
mixing a plurality of carbonaceous particles in a dielectric material; and
disposing the carbonaceous particle-containing dielectric material onto the substrate.

30. The method of claim 25, wherein the carbonaceous particles are diamond particles.

31. A light-emitting diode device having improved heat dissipation properties, comprising:
a light-emitting diode thermally coupled to the circuit of the device of claim 1, such that the dielectric layer is configured to accelerate heat movement away from the light-emitting diode.

32. A thermally dynamic printed circuit board device having improved heat dissipation properties, comprising:
a central processing unit thermally coupled to the circuit of the device of claim 1, such that the dielectric layer is configured to accelerate heat movement away from the central processing unit.

33. A thermally dynamic printed circuit board device for minimizing heat buildup, comprising:
an aluminum matrix having a plurality of diamond particles disposed therein;
an Al₂O₃ dielectric layer disposed onto a surface of the aluminum matrix, said dielectric layer being physically coupled to a portion of the plurality of diamond particles; and
a circuit including a heat source, said circuit being disposed onto the dielectric layer opposite to the aluminum matrix and being thermally coupled to the dielectric layer, said dielectric layer being configured to accelerate heat generated by the heat source away from the heat source.

34. The device of claim 33, wherein a portion of the plurality of diamond particles partially protrude from a surface of the aluminum matrix opposite the dielectric layer.
